(19) United States
(12) Patent Application Publication
(10) Pub. No.: US 2026/0267062 A1
(43) Pub. Date: Sep. 10, 2026

(54) Chip with multiple semiconductor optical amplifiers

(71) Applicant: Lyte AI Inc., Mountain View, CA (US)

(72) Inventors: Adam SCOFIELD, Los Angeles, CA (US); Arman HAJATI, San Carlos, CA (US)

(21) Appl. No.: 19/489,280

(22) PCT Filed: Jun. 6, 2024
(86) PCT No.: PCT/US2024/032680

§ 371 Date: Dec. 2, 2025

Related U.S. Application Data
(60) Provisional application No. 63/506,836, filed on Jun. 8, 2023.

(51) Int. Cl. G02B 6/12; G02B 6/124; G02B 6/14; G02F 1/095; H01S 5/00; H01S 5/0687; H01S 5/50

(52) U.S. Cl. CPC G02B 6/12004; G02B 6/124; G02B 6/14; G02F 1/0955; H01S 5/0014; H01S 5/0687; H01S 5/50; G02B 2006/12078; G02B 2006/12102; G02B 2006/1215

(57) ABSTRACT

An integrated optical device includes a laser, which generates an input beam, and an amplifier chip, which includes a plurality of semiconductor optical amplifiers on a semiconductor substrate. An optical splitter receives an input beam from the laser and splits it into multiple sub-beams. Multiple output waveguides convey the sub-beams to respective SOAs, which amplify the sub-beams. Multiple output couplers on the semiconductor substrate output the amplified sub-beams from the amplifier chip. A silicon photonic integrated circuit includes multiple input couplers, which are aligned respectively with the output couplers on the amplifier chip, and optical processing circuitry, which receives and processes one or more of the amplified sub-beams from the input couplers.

### CROSS-REFERENCE TO RELATED APPLICATION

This application claims the benefit of U.S. Provisional Patent Application 63/506,836, filed Jun. 8, 2023, which is incorporated herein by reference.

### FIELD

The present invention relates generally to integrated optoelectronic devices, and particularly to photonic integrated circuits and methods for their manufacture.

### BACKGROUND

Silicon photonic integrated circuits (SPICs) are commonly used in optical transmitter and transceiver arrays. Some active optoelectronic components, however, such as semiconductor lasers and semiconductor optical amplifiers (SOAs), comprise III-V semiconductor compounds (such as GaAs or InP). These components are typically fabricated on a III-V wafer. After fabrication, the III-V wafer is diced to produce singulated III-V chiplets, which are then aligned and mounted in the appropriate locations on the SPIC.

The terms “optical radiation” and “light” are used synonymously in the present description and in the claims to refer to electromagnetic radiation in any or all of the visible, infrared, and ultraviolet spectral ranges.

### SUMMARY

Embodiments of the present invention that are described hereinbelow provide improved integrated optoelectronic devices and methods for their manufacture.

There is therefore provided, in accordance with an embodiment of the invention, an integrated optical device, including a laser, configured generate an input beam of coherent radiation, and an amplifier chip, including a semiconductor substrate and a plurality of semiconductor optical amplifiers (SOAs) disposed on the semiconductor substrate. An optical splitter is disposed on the semiconductor substrate and is coupled to receive the input beam from the laser and to split the input beam into multiple sub-beams. Multiple output waveguides are disposed on the semiconductor substrate and coupled to convey the multiple sub-beams to respective ones of the SOAs, whereby the SOAs amplify the sub-beams. Multiple output couplers are disposed on the semiconductor substrate and coupled to receive the amplified sub-beams from the SOAs and to output the amplified sub-beams from the amplifier chip. A silicon photonic integrated circuit (SPIC) includes multiple input couplers, which are aligned respectively with the output couplers on the amplifier chip so as to receive the amplified sub-beams. Optical processing circuitry is disposed on the SPIC and configured to receive and process one or more of the amplified sub-beams from the input couplers.

In a disclosed embodiment, the semiconductor substrate includes a III-V semiconductor compound. In one embodiment, the laser is disposed on the semiconductor substrate of the amplifier chip.

Additionally or alternatively, the optical processing circuitry includes an interferometer disposed on the SPIC, which is configured to sense a frequency variation in at least one of the amplified sub-beams. The device includes control circuitry configured to drive the laser responsively to the sensed frequency variation. In a disclosed embodiment, the control circuitry is configured to apply a frequency chirp to the input beam while linearizing the chirp responsively to the sensed frequency variation.

In some embodiments, the device includes an array of microlenses disposed between the output couplers on the semiconductor substrate and the input couplers on the SPIC. Additionally or alternatively, the device includes an optical isolator configured to pass the amplified sub-beams from the output couplers on the semiconductor substrate to the input couplers on the SPIC while attenuating back-reflections from the SPIC to the semiconductor substrate.

In some embodiments, the amplifier chip includes a receiving waveguide coupled to convey the input beam to the optical splitter, and the SPIC includes a laser waveguide, which is coupled to convey the input beam to the receiving waveguide. In one embodiment, the plurality of SOAs includes an input SOA, which is disposed between the receiving waveguide and the optical splitter and configured to amplify the input beam before the input beam is split into the multiple sub-beams. In a disclosed embodiment, the laser is disposed on the SPIC.

Additionally or alternatively, the device includes an array of microlenses, including first microlenses disposed between the output couplers on the semiconductor substrate and the input couplers on the SPIC and a second microlens disposed between the laser waveguide on the SPIC and the receiving waveguide on the amplifier chip. In one embodiment, the device includes an optical isolator, including a Faraday rotator and a waveplate, coupled in series with the array of microlenses and configured to attenuate back-reflections of the amplified sub-beams from the SPIC to the amplifier chip. A polarization rotator is coupled in series with the laser waveguide on the SPIC and configured to rotate a polarization of the input beam prior to passage of the input beam through the optical isolator.

In one embodiment, the output couplers and input couplers include edge couplers. Alternatively, the output couplers and input couplers include grating couplers.

In a disclosed embodiment, the amplifier chip includes at least one tap coupled to sample at least one of the amplified sub-beams for monitoring or testing. Additionally or alternatively, the amplifier chip includes optical mode converters disposed in series with the SOAs.

In some embodiments, the plurality of the SOAs is divided into multiple subsets, each subset including two or more of the SOAs connected in series by interconnecting waveguides and configured to amplify a respective one of the sub-beams. In a disclosed embodiment, the SOAs are disposed parallelly on the amplifier chip, and the interconnecting waveguides are curved.

In some embodiments, the optical splitter includes a wavelength splitter, whereby the multiple sub-beams have different, respective wavelengths. In one embodiment, the device includes a beam combiner, which is configured to multiplex the amplified sub-beams into a combined multi-wavelength output beam.

There is also provided, in accordance with an embodiment of the invention, a method for optical beam generation, which includes providing an amplifier chip including a semiconductor substrate and a plurality of semiconductor optical amplifiers (SOAs) disposed on the semiconductor substrate. An optical splitter is disposed on the semiconductor substrate and is coupled to receive an input beam of coherent radiation and to split the input beam into multiple sub-beams. Multiple output waveguides are disposed on the semiconductor substrate and coupled to convey the multiple sub-beams to respective ones of the SOAs, whereby the SOAs amplify the sub-beams. Multiple output couplers are disposed on the semiconductor substrate and coupled to receive the amplified sub-beams from the SOAs and to output the amplified sub-beams from the amplifier chip. A silicon photonic integrated circuit (SPIC), including multiple input couplers, is aligned with the amplifier chip such that the input couplers receive the amplified sub-beams from respective ones of the output couplers on the amplifier chip. One or more of the amplified sub-beams are processed using optical processing circuitry on the SPIC.

The present invention will be more fully understood from the following detailed description of the embodiments thereof, taken together with the drawings in which:

### BRIEF DESCRIPTION OF THE DRAWINGS

FIGS. 1, 2, 3, 4, 5 and 6 are schematic top views of multichannel optical transmitters, in accordance with embodiments of the invention;

FIG. 7 is a schematic top view of an optical splitter and amplifier chip, in accordance with an embodiment of the invention;

FIGS. 8A and 8B are schematic top and side views, respectively, of a multichannel optical transmitter, in accordance with another embodiment of the invention;

FIGS. 9A and 9B are schematic detail views of optical amplifier chips with mode converters, in accordance with embodiments of the invention;

FIGS. 10A and 10B are schematic detail views of optical amplifier chips with multiple amplification stages, in accordance with embodiments of the invention; and

FIGS. 11A and 11B are schematic top view of optical amplifier and beam combiner chips, in accordance with embodiments of the invention.

### DETAILED DESCRIPTION

### Overview

Some optical transmitter and transceiver devices include multiple transmission channels, each with its own SOA. When each SOA is mounted on its own III-V chiplet, as described above in the Background section, the difficulty and cost of aligning all the SOAs with the appropriate waveguides on the SPIC can be substantial.

Embodiments of the present invention address this problem by fabricating multiple SOAs on a single III-V chip, together with respective input and output waveguides. A splitter can be used to divide an input laser beam among the input waveguides. The splitter and waveguides on the III-V chip are fabricated together with the SOAs using III-V materials, and thus the SOAs are inherently aligned with the waveguides. The multiple outputs of the III-V chip, each provided by a respective SOA, can then be aligned with the corresponding channels on a SPIC in a single inter-chip alignment operation.

Thus, the embodiments that are described hereinbelow provide an integrated optical device, comprising a laser, configured generate an input beam of coherent radiation, an amplifier chip, and a silicon photonic integrated circuit (SPIC). The amplifier chip comprises a semiconductor substrate, comprising a III-V semiconductor compound, for example. An optical splitter on the semiconductor substrate receives the input beam from the laser and splits it into multiple sub-beams. Multiple output waveguides on the semiconductor substrate convey the sub-beams to respective SOAs on the same substrate, whereby the SOAs amplify the sub-beams.

Multiple output couplers on the semiconductor substrate of the amplifier chip receive the amplified sub-beams from the SOAs and output the amplified sub-beams from the amplifier chip to corresponding input couplers on the SPIC, which are aligned respectively with the output couplers. As the output couplers and input couplers are formed by precise photolithography on their respective substrates, aligning one output/input coupler pair will inherently align all the other pairs. Thus, only a single alignment step is needed to align them all.

Optical processing circuitry on the SPIC receives and processes one or more of the amplified sub-beams from the input couplers. For example, the optical processing circuitry may comprise an interferometer on the SPIC, which is used to sense a frequency variation in at least one of the amplified sub-beams and provides an input to control circuitry for driving the laser with precise frequency control.

The embodiments that are described below provide implementations of and variations on these chip and system architectures.

### Device Designs

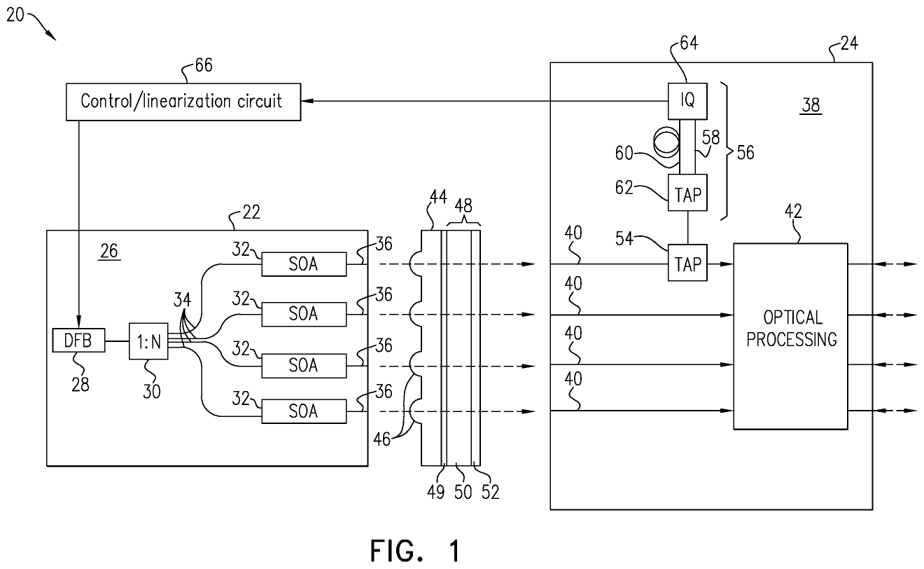

FIG. 1 is a schematic top view of a multichannel optical transmitter 20, in accordance with an embodiment of the invention. Transmitter 20 is an integrated optical device comprising an amplifier chip 22 and a silicon photonic integrated circuit SPIC 24.

Amplifier chip 22 comprises a semiconductor substrate 26, for example a III-V substrate, such as GaAs or InP. A laser 28 on substrate 26, such as a distributed feedback (DFB) laser, generates an input beam of coherent radiation. An optical splitter 30 on substrate 26 receives the input beam from laser 28 and splits the input beam into N sub-beams (N=4 in the pictured examples). Splitter 30 may comprise, for example, a binary tree of 1:2 splitters, such as Y junctions, or one or more multimode interferometers (MMIs).

Amplifier chip 22 further comprises multiple SOAs 32, which are fabricated on substrate 26 by processes of thin film deposition and photolithography, as are known in the art. Multiple output waveguides 34 on substrate 26 convey the sub-beams from splitter 30 to respective ones of the SOAs 32. Electrical bias applied to the SOAs 32 causes the SOAs to amplify the sub-beams. Output couplers 36, such as edge couplers, on substrate 26 receive the amplified sub-beams from the SOAs 32 and output the amplified sub-beams from amplifier chip 22.

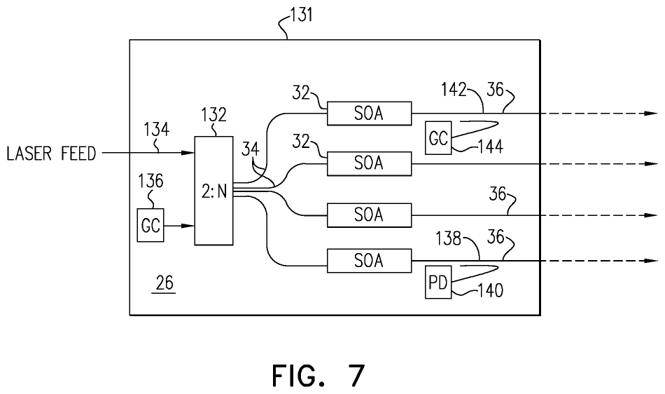

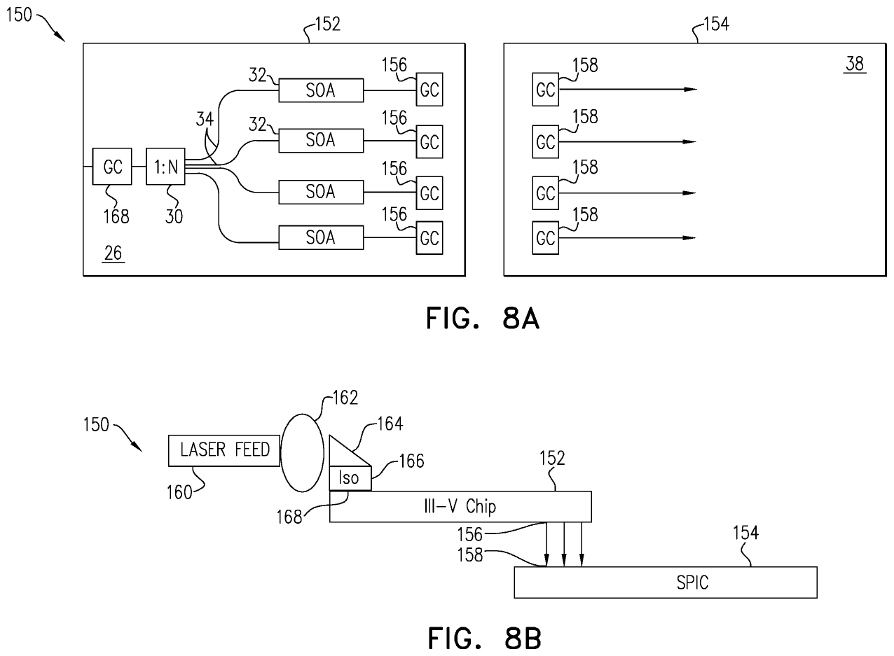

SPIC 24 comprises a silicon-based substrate 38, such as a silicon-on-insulator (SOI) substrate. Multiple input couplers 40 on substrate 38 are aligned respectively with output couplers 36 on amplifier chip 22 so as to receive the amplified sub-beams. Input couplers 40 in this example similarly comprise edge couplers. Alternatively, other sorts of input and output couplers may be used, such as grating couplers (as illustrated in FIGS. 8A/B). To improve coupling efficiency, an array 44 of microlenses 46 is aligned between output couplers 36 on substrate 26 and input couplers 40 on the SPIC 24.

In addition, an optical isolator 48 is coupled in series with array 44 to pass the amplified sub-beams from output couplers 36 to input couplers 40 while attenuating back-reflections from SPIC 24 to amplifier chip 22. In the present example, optical isolator 48 comprises a polarizer 49, a Faraday rotator 50, and a waveplate 52. Waveplate 52 typically comprises a half-wave plate. Polarizer 49 is optional, since the output of SOAs 32, as well as of laser 28, is typically polarized in the TE-mode direction. Back-reflections will be rotated by Faraday rotator 50 and waveplate 52 to the TM-mode direction and will therefore have little effect on SOAs 32 and laser 28 even in the absence of polarizer 49. Alternatively, other sorts of optical isolators may be used, as are known in the art.

Optical processing circuitry 42 on SPIC 24 receives and processes one or more of the amplified sub-beams from the input couplers 40. For example, optical processing circuitry 42 may comprise an optical distribution network, which distributes the amplified sub-beams among an array of transmitter or transceiver cells, such as the sorts of cells that are described in PCT International Publication WO 2023/023106, whose disclosure is incorporated herein by reference.

In the present example, the optical processing circuitry on SPIC 24 also includes an interferometer 56, comprising a reference arm 58 and a delay arm 60, defined by waveguides formed on substrate 38. An optical tap 54 samples a small fraction (for example 1%) of the energy in the sub-beam that is received by one of input couplers 40 and directs it to interferometer 56. A further tap 62 divides the sampled beam between reference arm 58 and delay arm 60. An optical beat detector 64, such as a set of balanced photodiodes connected to an optical hybrid, senses the frequency variation in the sampled sub-beam. Alternatively, multiple sub-beams may be sampled and sensed.

Control circuitry 66 receives the electrical output from detector 64 and uses it as a feedback signal for driving laser 28. For example, when transmitter 20 is used as part of a frequency-modulated continuous-wave (FMCW) LiDAR system, control circuitry 66 may apply a frequency chirp to the input beam generated by laser 28. Circuitry 66 detects and corrects deviations from linearity of the chirp based on the frequency variation sensed by detector 64. For the sake of simplicity, control circuitry 66 is omitted from the figures that follow.

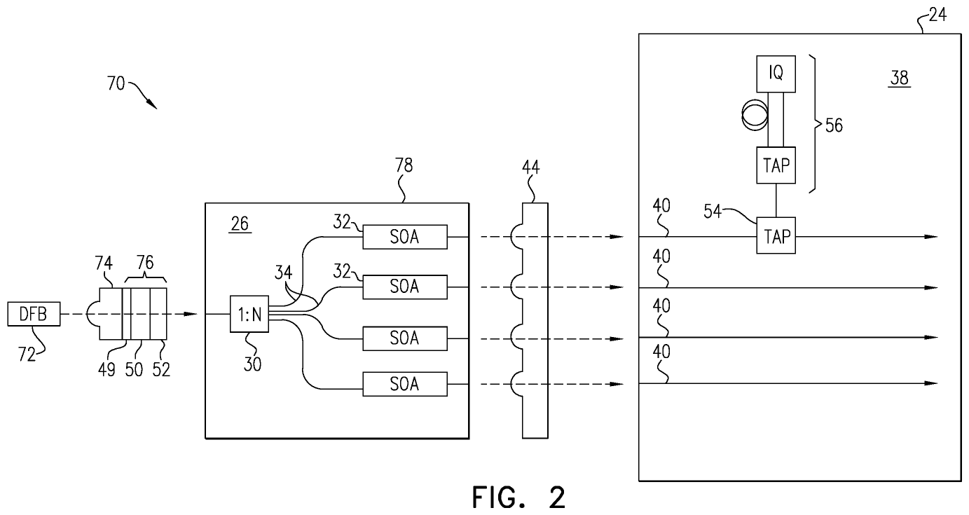

FIG. 2 is a schematic top view of a multichannel optical transmitter 70, in accordance with another embodiment of the invention. In this and the subsequent figures, the same reference numbers are used as in FIG. 1 to identify elements of similar structure and functionality to those that are described above. The descriptions of these elements will not be repeated except as required for clarity of explanation.

In the present embodiment, transmitter 70 comprises a separate laser 72, which generates the input beam to a III-V amplifier chip 78. The input beam is conveyed to splitter 30 via a microlens 74 and an optical isolator 76, which prevents back-reflection from the amplifier chip to the laser.

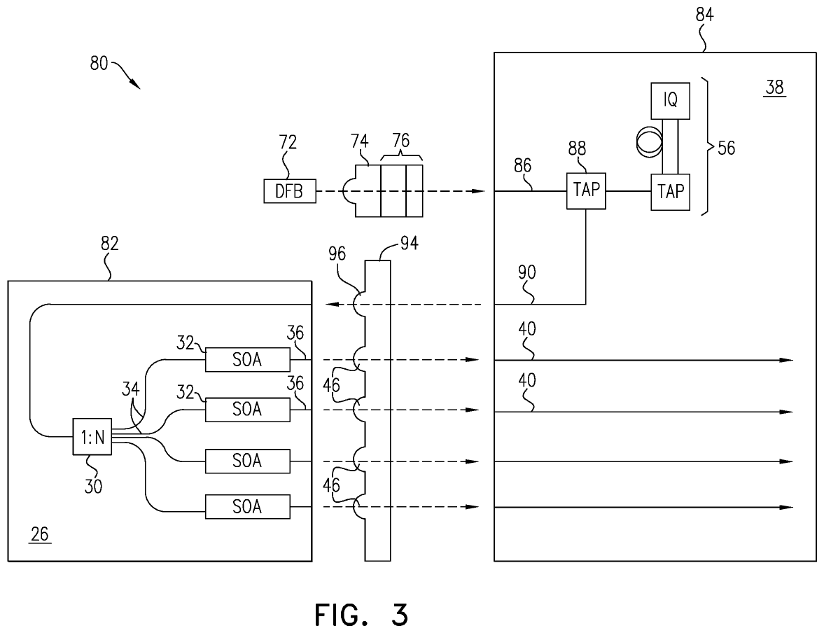

FIG. 3 is a schematic top view of a multichannel optical transmitter 80, in accordance with yet another embodiment of the invention. In this embodiment, the beam from laser 72 is focused into an input laser waveguide 86 on substrate 38 of a SPIC 84. A sampling tap 88 splits off a small fraction of the laser energy in waveguide 86 for input to interferometer 56, which provides a feedback signal to control circuitry, as described above. The remaining laser energy is output via an output laser waveguide 90 on SPIC 84 to a receiving waveguide 92 on an amplifier chip 82.

An array 94 of microlenses 46, 96 is aligned between amplifier chip 82 and SPIC 84. Microlenses 46 are positioned between output couplers 36 on semiconductor substrate 26 and input couplers 40 on SPIC 84. Microlens 96 is positioned between output laser waveguide 90 on SPIC 84 and receiving waveguide 92 on amplifier chip 82. Because all the waveguides, couplers, and microlenses are formed by lithographic processes, their relative locations are well controlled. It is thus possible to align amplifier chip 82, SPIC 84 and microlens array 94 in a single alignment step.

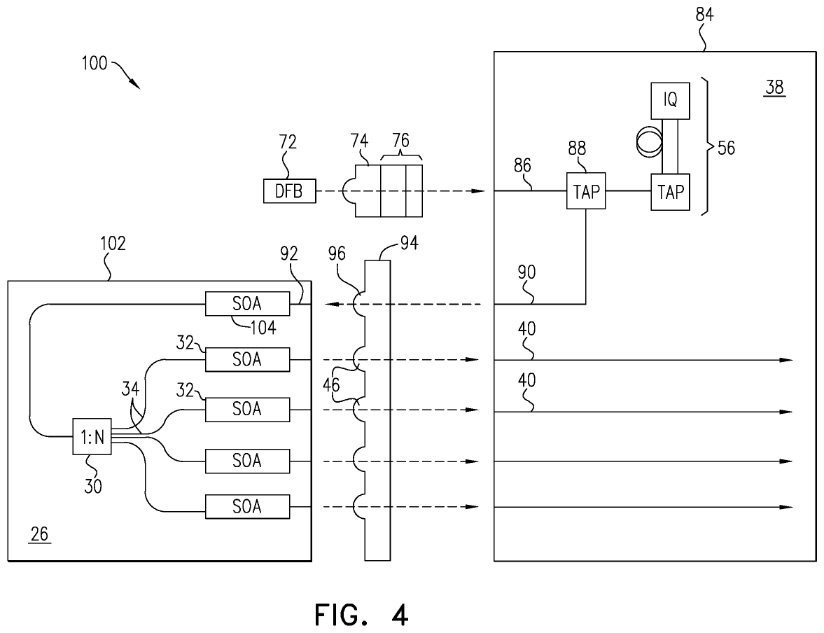

FIG. 4 is a schematic top view of a multichannel optical transmitter 100, in accordance with a further embodiment of the invention. This embodiment is similar to transmitter 80 (FIG. 3), except that transmitter 100 comprises an amplifier chip 102 that includes an input SOA 104, in series with SOAs 32, to increase the overall gain of the amplifier chip. Input SOA 104 is interposed between receiving waveguide 92 and optical splitter 30 to amplify the input beam before the input beam is split into the multiple sub-beams for amplification by SOAs 32.

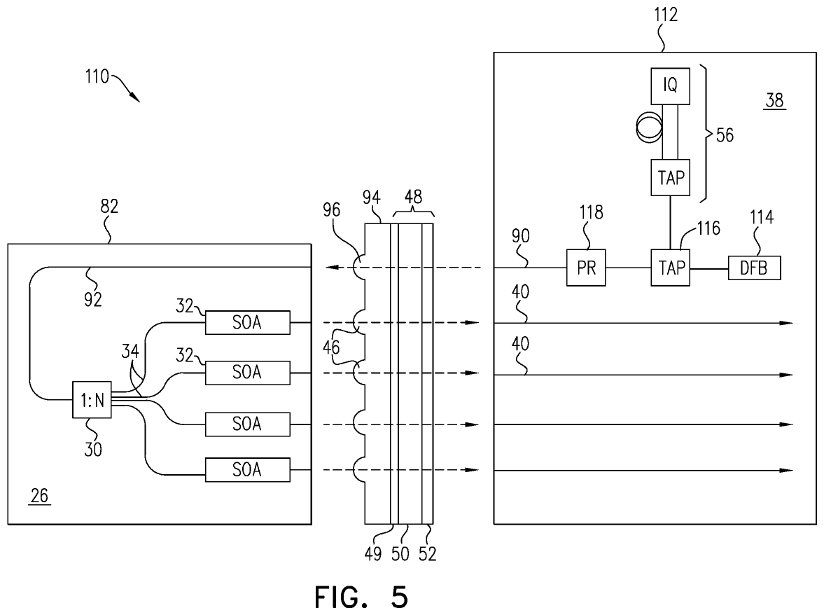

FIG. 5 is a schematic top view of a multichannel optical transmitter 110, in accordance with an alternative embodiment of the invention. Transmitter 110 comprises a SPIC 112, which includes a laser 114 formed or mounted (for example in a flip-chip package) on substrate 38 of SPIC 112. A sampling tap 116 on SPIC 112 splits off a small fraction of the laser energy for input to interferometer 56, which senses frequency deviations as in the embodiments described above. The present embodiment is advantageous in that laser 114 is pre-aligned on substrate 38 of SPIC 112, and thus only a single inter-chip alignment step, between chip 82 and SPIC 112, is needed to align all the components of transmitter 110.

Optical isolator 48 attenuates back-reflections in both directions of the optical links between chip 82 and SPIC 112. As the input beam generated by laser 114 is typically TE-polarized, a polarization rotator 118 is coupled in series with laser waveguide 90 on SPIC 112 to rotate the polarization of the input beam to the TM-polarization prior to passage of the beam through optical isolator 48. The optical isolator rotates the polarization of the input beam back to the TE direction for input to receiving waveguide 92.

In a further alternative embodiment (not shown in the figures), the amplifier chip in transmitter 110 includes an input SOA between receiving waveguide 92 and optical splitter 30, as in the embodiment of FIG. 4. An input SOA may similarly be incorporated at the input to amplifier chip 78 in the embodiment of FIG. 2, to amplify the input beam from laser 72 before inputting the beam to splitter 30. The use of the input SOA in these alternative embodiments makes it possible to use a laser source with lower power.

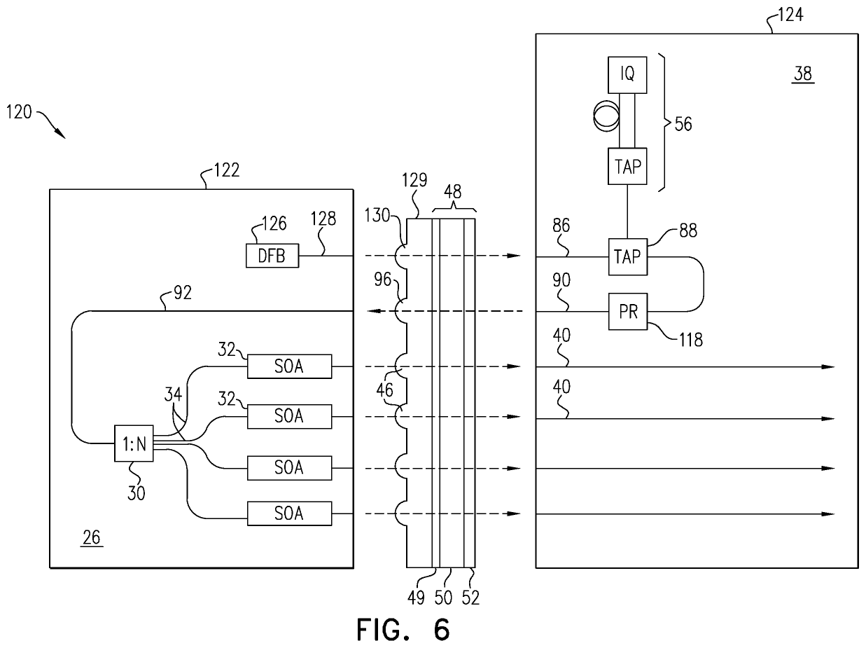

FIG. 6 is a schematic top view of a multichannel optical transmitter 120, comprising an amplifier chip 122 and a SPIC 124, in accordance with an additional embodiment of the invention. This embodiment is similar in operation to the embodiment of FIG. 5, except that in the present embodiment, a laser 126 is formed or mounted on amplifier chip 122. The input beam generated by laser 126 is output via an output laser waveguide 128 to input laser waveguide 86 on substrate 38 of SPIC 124. A microlens array 129 between amplifier chip 122 and SPIC 124 includes a microlens 130 focusing the beam from output laser waveguide 128 into input laser waveguide 86, in addition to microlenses 46 and 96 as described above. As in the embodiment of FIG. 5, only a single inter-chip alignment step, between chip 122 and SPIC 124, is needed to align all the components of transmitter 120.

As in the preceding embodiments, amplifier chip 122 may optionally include an input SOA between receiving waveguide 92 and optical splitter 30.

### Alternative Features and Configurations

FIG. 7 is a schematic top view of an optical splitter and amplifier chip 131, in accordance with an embodiment of the invention. The features of chip 131 may be incorporated, in whole or in part, into the amplifier chips of the preceding embodiments.

At the input side, chip 131 includes a 2: N splitter 132, which makes it possible to align two lasers to input beams to the chip, for example to provide redundancy in case of failure or to provide input at multiple wavelengths. Either an edge coupler 134 or a surface coupler, such as a grating coupler 136, can be used for laser beam input. To increase the efficiency of grating coupler 136 (as well as other grating couplers that are described below), additional distributed Bragg reflection (DBR) lasers can be added to the epitaxial structure on chip 131 above and/or below the grating coupler itself.

Additionally or alternatively, chip 131 includes a monitoring tap 138 at the output of one of SOAs 32 and/or an output tap 142 at the output of another SOA. Monitoring tap 138 samples a small fraction of the energy output by the SOA to a detector, such as a photodiode 140, for purposes of performance monitoring. Photodiode 140 may comprise, for example, a segment of waveguide made from a III-V material, which is doped and reverse-biased to generate a photocurrent in response to the light fed from tap 138. Output tap 142 samples a small fraction of the energy output by another SOA to a grating coupler 144, whose output can be used, for example, for purposes of wafer-level testing, as well as alignment.

FIGS. 8A and 8B are schematic top and side views, respectively, of a multichannel optical transmitter 150, in accordance with another embodiment of the invention. Transmitter 150 comprises an amplifier chip 152 and a SPIC 154, which are similar in structure and functionality to the amplifier chips and SPICs shown in the preceding embodiments. In transmitter 150, however, the amplified sub-beams generated by SOAs 32 are output vertically by respective grating couplers 156, which are aligned with respective grating couplers 158 on SPIC 154.

A laser 160 may similarly be coupled to transfer the input beam to splitter 30 via a grating coupler 168 on amplifier chip 152. In the example shown in FIG. 8B, the beam from laser 160 is directed by a lens 162 and a turning mirror 164 toward grating coupler 168. An optical isolator 166 may be interposed in the laser beam path to attenuate back-reflections.

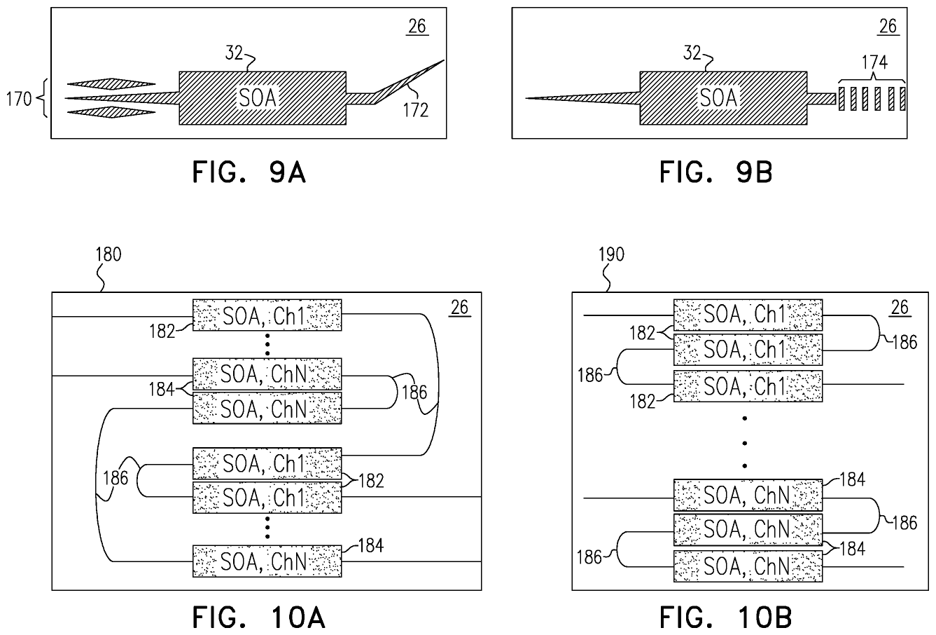

FIGS. 9A and 9B are schematic detail views of optical amplifier chips with mode converters, which are formed in series with SOAs 32, in accordance with further embodiments of the invention. The purpose of these mode converters is to reshape the beam received from the laser to an optimal mode field diameter (MFD). Various types of mode converter can be used for this purpose, such as a trident edge coupler 170, an inverse-tapered edge coupler 172, or a metamaterial coupler 174. In the pictured embodiment, edge coupler 172 is angled to reduce back-reflection into SOA 32.

FIGS. 10A and 10B are schematic detail views of optical amplifier chips 180, 190 with multiple amplification stages, in accordance with alternative embodiments of the invention. Splitters 30 and other components are omitted from these figures for the sake of simplicity.

In chips 180 and 190, the SOAs are divided into multiple subsets, which are marked as SOAs 182, SOAs 184, and so forth. The SOAs is each subset are arranged in series, interconnected by waveguides 186, so that each subset amplifies a respective sub-beam, marked in the figure as channel 1 (Ch1) through channel N (ChN). The use of multiple amplification stages in series increases the overall gain and output power of the amplified sub-beams. For compact design, SOAs 182 and 184 are geometrically parallel on chips 180 and 190, and interconnecting waveguides 186 are curved. The SOAs may be separated from one another by deep trenches in substrate 26 to reduce thermal crosstalk.

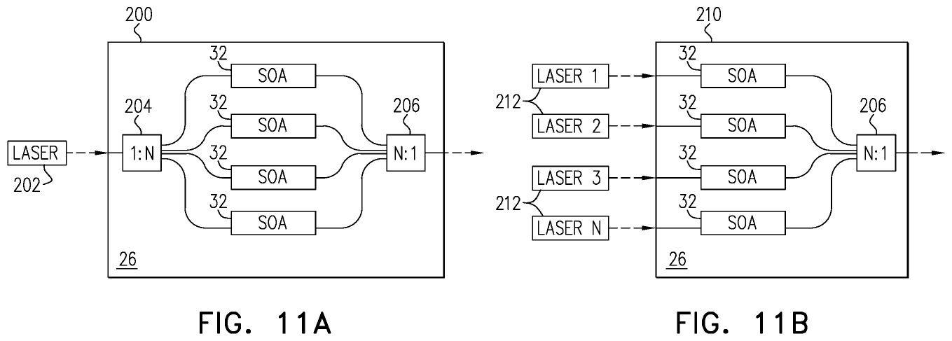

FIG. 11A is a schematic detail view of an optical amplifier and beam combiner chip 200, in accordance with a further alternative embodiment of the invention. Chip 200 receives a multi-wavelength input beam from a laser 202. A wavelength splitter 204 divides the input beam by wavelength among multiple SOAs 32, each of which thus amplifies a respective wavelength. Splitter 204 may comprise, for example, an arrayed waveguide grating (AWG) or a Mach Zehnder interferometer (MZI) component. The amplified sub-beams output by SOAs may be input to respective input couplers on a SPIC, as in the embodiments described above.

Alternatively, as shown in FIG. 11A, a beam combiner 206 may multiplex the amplified sub-beams into a combined multi-wavelength output. Beam combiner 206 may similarly comprise an AWG or MZI component.

FIG. 11B is a schematic detail view of an optical amplifier and beam combiner chip 210, in accordance with another embodiment of the invention. In this case, the input beams to chip 210, at multiple different wavelengths, are generated by separate lasers 212. These beams are then amplified by respective SOAs 32 and combined by beam combiner 206 as described above.

The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An integrated optical device, comprising:
a laser, configured generate an input beam of coherent radiation;
an amplifier chip, comprising:
a semiconductor substrate;
a plurality of semiconductor optical amplifiers (SOAs) disposed on the semiconductor substrate;
an optical splitter, which is disposed on the semiconductor substrate and is coupled to receive the input beam from the laser and to split the input beam into multiple sub-beams;
multiple output waveguides disposed on the semiconductor substrate and coupled to convey the multiple sub-beams to respective ones of the SOAs, whereby the SOAs amplify the sub-beams; and
multiple output couplers disposed on the semiconductor substrate and coupled to receive the amplified sub-beams from the SOAs and to output the amplified sub-beams from the amplifier chip; and
a silicon photonic integrated circuit (SPIC), comprising:
multiple input couplers, which are aligned respectively with the output couplers on the amplifier chip so as to receive the amplified sub-beams; and
optical processing circuitry disposed on the SPIC and configured to receive and process one or more of the amplified sub-beams from the input couplers.

2. The device according to claim 1, wherein the semiconductor substrate comprises a III-V semiconductor compound.

3. The device according to claim 1, wherein the laser is disposed on the semiconductor substrate of the amplifier chip.

4. The device according to claim 1, wherein the optical processing circuitry comprises an interferometer disposed on the SPIC, which is configured to sense a frequency variation in at least one of the amplified sub-beams, and
wherein the device comprises control circuitry configured to drive the laser responsively to the sensed frequency variation.

5. The device according to claim 4, wherein the control circuitry is configured to apply a frequency chirp to the input beam while linearizing the chirp responsively to the sensed frequency variation.

6. The device according to claim 1, and comprising an array of microlenses disposed between the output couplers on the semiconductor substrate and the input couplers on the SPIC.

7. The device according to claim 1, and comprising an optical isolator configured to pass the amplified sub-beams from the output couplers on the semiconductor substrate to the input couplers on the SPIC while attenuating back-reflections from the SPIC to the semiconductor substrate.

8. The device according to claim 1, wherein the amplifier chip comprises a receiving waveguide coupled to convey the input beam to the optical splitter, and wherein the SPIC comprises a laser waveguide, which is coupled to convey the input beam to the receiving waveguide.

9. The device according to claim 8, wherein the plurality of SOAs comprises an input SOA, which is disposed between the receiving waveguide and the optical splitter and configured to amplify the input beam before the input beam is split into the multiple sub-beams.

10. The device according to claim 8, wherein the laser is disposed on the SPIC.

11. The device according to claim 8, and comprising an array of microlenses comprising first microlenses disposed between the output couplers on the semiconductor substrate and the input couplers on the SPIC and a second microlens disposed between the laser waveguide on the SPIC and the receiving waveguide on the amplifier chip.

12. The device according to claim 11, and comprising:
an optical isolator, comprising a Faraday rotator and a waveplate, coupled in series with the array of microlenses and configured to attenuate back-reflections of the amplified sub-beams from the SPIC to the amplifier chip; and
a polarization rotator coupled in series with the laser waveguide on the SPIC and configured to rotate a polarization of the input beam prior to passage of the input beam through the optical isolator.

13. The device according to claim 1, wherein the output couplers and input couplers comprise edge couplers.

14. The device according to claim 1, wherein the output couplers and input couplers comprise grating couplers.

15. The device according to claim 1, wherein the amplifier chip comprises at least one tap coupled to sample at least one of the amplified sub-beams for monitoring or testing.

16. The device according to claim 1, wherein the amplifier chip comprises optical mode converters disposed in series with the SOAs.

17. The device according to claim 1, wherein the plurality of the SOAs is divided into multiple subsets, each subset comprising two or more of the SOAs connected in series by interconnecting waveguides and configured to amplify a respective one of the sub-beams.

18. The device according to claim 17, wherein the SOAs are disposed parallelly on the amplifier chip, and the interconnecting waveguides are curved.

19. The device according to claim 1, wherein the optical splitter comprises a wavelength splitter, whereby the multiple sub-beams have different, respective wavelengths.

20. The device according to claim 19, and comprising a beam combiner, which is configured to multiplex the amplified sub-beams into a combined multi-wavelength output beam.

21. A method for optical beam generation, comprising:
providing an amplifier chip comprising:
a semiconductor substrate;
a plurality of semiconductor optical amplifiers (SOAs) disposed on the semiconductor substrate;
an optical splitter, which is disposed on the semiconductor substrate and is coupled to receive an input beam of coherent radiation and to split the input beam into multiple sub-beams;
multiple output waveguides disposed on the semiconductor substrate and coupled to convey the multiple sub-beams to respective ones of the SOAs, whereby the SOAs amplify the sub-beams; and
multiple output couplers disposed on the semiconductor substrate and coupled to receive the amplified sub-beams from the SOAs and to output the amplified sub-beams from the amplifier chip;
aligning a silicon photonic integrated circuit (SPIC) comprising multiple input couplers with the amplifier chip such that the input couplers receive the amplified sub-beams from respective ones of the output couplers on the amplifier chip; and
processing one or more of the amplified sub-beams using optical processing circuitry on the SPIC.

22-40. (canceled)
